(19) United States
(12) Patent Application Publication
(10) Pub. No.: US 2023/0041090 A1
(43) Pub. Date: Feb. 9, 2023

(54) METHODS FOR COATING NANO-ORDERED CARBON MATERIALS

(71) Applicant: PHILLIPS 66 COMPANY, Houston, TX (US)

(72) Inventors: Kan Huang, Sterling Heights, MI (US); Liang Zhang, Owasso, OK (US); Alexander Z. Wilbee, Bartlesville, OK (US); Brian J. Worfolk, Raliegh, NC (US)

(73) Assignee: PHILLIPS 66 COMPANY, Houston, TX (US)

(21) Appl. No.: 17/873,536

(22) Filed: Jul. 26, 2022

Related U.S. Application Data
(60) Provisional application No. 63/230,868, filed on Aug. 9, 2021.
(60) Provisional application No. 63/304,811, filed on Jan. 31, 2022.
(60) Provisional application No. 63/304,952, filed on Jan. 31, 2022.

(51) Int. Cl. H01M 4/587; H01M 4/36; C23C 16/44; C23C 16/26; C23C 18/12; C01B 32/15

(52) U.S. Cl. CPC H01M 4/587; C01B 32/15; C23C 16/26; C23C 16/4408; C23C 18/127; C23C 18/1204; C23C 18/1245; H01M 4/366; H01M 2004/027

(57) ABSTRACT

Embodiments of the present disclosure generally relate to carbon materials for battery electrodes and methods for preparing such carbon materials. More specifically, embodiments relate to methods for coating a carbon film onto nano-ordered carbon particles to produce carbon-coated particles which can be used as an anode material within a battery, such as a lithium-ion battery, a sodium-ion battery, other types of batteries. In one or more embodiments, a method for producing carbon-coated particles is provided and includes positioning nano-ordered carbon particles within a processing region of a processing chamber, purging the processing region containing the nano-ordered carbon particles with an inert gas, heating the nano-ordered carbon particles to a temperature of about 700° C. or greater during an annealing process, and depositing a carbon film on the nano-ordered carbon particles to produce carbon-coated particles during a vapor deposition process.

### CROSS-REFERENCE TO RELATED APPLICATIONS

This application is a Non-Provisional application which claims the benefit of and priority to U.S. Provisional Application Serial No. 63/230,868 filed Aug. 9, 2021, entitled "Multi Functionalization of Petroleum Products," U.S. Provisional Application Serial No. 63/304,811 filed Jan. 31, 2022, entitled "Methods for Preparing Nano-Ordered Carbon Products from Petroleum Streams" and U.S. Provisional Application Serial No. 63/304,952 filed Jan. 31, 2022, entitled "Methods for Coating Hard Carbon" all of which are hereby incorporated by reference in their entirety.

### BACKGROUND

### Field

Embodiments of the present disclosure generally relate to battery technology, and more specifically, methods for preparing carbon-based materials used in battery technology.

### Description of the Related Art

Alkali ion rechargeable batteries such as lithium ion or sodium ion batteries play critical role in global electrification and enabling wide adoption of low carbon intensity or renewable energies. Graphite is currently the most common anode materials in Li-ion batteries due to its preferred lithiation and delithiation profiles. However, the relatively lower theoretical capacity (372 mAh/g) of graphite is throttling the constant demand in the industry of increasing battery energy density. In addition, the market desire for fast charge and low temperature performance is also directing R&D effort toward other anode material options. Carbon materials with nano-ordered structures, such as nongraphizable carbon (or hard carbon), attracted material developers due to its potentially larger capacity (> 372 mAh/g) and better performance in power and low temperature applications. While in use within a sodium or lithium-ion battery, the original nano-ordered carbon anode suffers from lower first cycle efficiency (FCE) than that of the state of art graphite anode in lithium-ion batteries due to parasitic side reactions during battery charge/discharge. Over time, these side reactions of the carbon could damage the anode which reduces the life-expectancy of the battery. Also, these side reactions to the anode can greatly reduce the first cycle efficiency (FCE) of the battery.

Therefore, there is a need for nano-ordered anode materials to reduce parasitic side reactions and improve the FCE to while maintaining or increasing the achievable capacity, and scalable methods for coating anode materials to achieve such effects.

### SUMMARY

Embodiments of the present disclosure generally relate to carbon materials for battery electrodes and methods for preparing such carbon materials. More specifically, embodiments relate to carbon-coated particles and methods for coating a carbon film onto nano-ordered carbon particles or hard carbon particles to produce the carbon-coated particles which can be used as an anode material within a rechargeable battery, such as a lithium-ion battery, a sodium-ion battery, other types of batteries.

In one or more embodiments, a method for producing carbon-coated particles is provided and includes positioning nano-ordered carbon particles within or passing the carbon particles through a processing region of a processing chamber, purging the processing region containing the nano-ordered carbon particles with an inert gas, heating the processing region and the nano-ordered carbon particles to a temperature of about 700° C. or greater, and depositing a carbon film on the nano-ordered carbon particles to produce carbon-coated particles during a thermo decomposition and/or a vapor deposition process.

In other embodiments, a method for producing carbon-coated particles is provided and includes positioning nano-ordered carbon particles within a processing region of a processing chamber, where the nano-ordered carbon particles have an average particle size of about 1 µm to about 50 µm and purging the processing region containing the nano-ordered carbon particles with an inert gas. The method also includes heating the nano-ordered carbon particles, to a temperature of about 700° C. to about 2,000° C. for about 0.5 minutes to about 20 minutes and introducing a carbon-containing precursor containing acetylene or toluene into the processing region and exposing the nano-ordered carbon particles to the carbon-containing precursor while depositing a carbon film on the nano-ordered carbon particles and producing carbon-coated particles during a thermal decomposition and/or vapor deposition process, where the carbon film has a thickness of about 1 nm to about 5 µm.

In some embodiments, a composition of carbon-coated particles has an irreversible capacity of less than 55 mAh/g in a battery voltage of about 0 V to about 3 V and a first cycle efficiency of greater than 84%. Each carbon-coated particle contains a carbon film disposed over a hard carbon particle. The nano-ordered carbon particles have an average particle size of about 1 µm to about 50 µm. The carbon film has a thickness of about 1 nm to about 5 µm. The carbon-coated particles have a pore size of about 1 nm to about 3 nm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a graph illustrating voltage versus capacity after a first cycle for a battery containing coated hard carbon compared to a control battery containing non-coated hard carbon, as described and discussed in one or more embodiments herein.

FIG. 1B is a graph illustrating voltage versus capacity after a second cycle for a battery containing coated hard carbon compared to a control battery containing non-coated hard carbon, as described and discussed in one or more embodiments herein.

FIG. 2A is a graph illustrating a comparison of the first and second charge profiles of a control battery containing non-coated hard carbon.

FIG. 2B is a graph illustrating a comparison of the first and second charge profiles of a battery containing coated hard carbon, as described and discussed in one or more embodiments herein.

FIG. 3A depicts a schematic coating on a hard carbon particle.

FIG. 3B depicts high resolution SEM images before coating.

FIG. 3C depicts high resolution SEM images after coating.

FIG. 4A depicts a graph of reversible capacities in sodium ion half cells for hard carbon samples before and after coating.

FIG. 4B depicts a graph of FCEs in sodium ion half cells for hard carbon samples before and after coating.

FIG. 4C depicts a graph of irreversible capacities in sodium ion half cells for hard carbon samples before and after coating.

FIG. 5A depicts the reversible capacity in sodium ion half cells for nano-ordered carbon C1100 before and after coating.

FIG. 5B depicts the FCE in lithium-ion half cells for hard carbon C1100 before and after coating.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to carbon materials for battery electrodes and methods for preparing such carbon materials. More specifically, embodiments relate to carbon-coated particles (e.g., coated hard carbon) and methods for coating nano-ordered carbon particles with a carbon film by a vapor deposition process in order to produce carbon-coated particles. The carbon-coated particles can be used as or within electrodes, such as an anode or an anode material. The carbon-coated particles provide reduced parasitic side reactions when compared to traditional nano-ordered carbon particles without a carbon coating. As such, the carbon-coated particles improve the first cycle efficiency (FCE) for carbon-based anode materials while maintaining or increasing the achievable capacity of the battery. The carbon-coated particles can be used in a variety of batteries, including lithium-ion batteries and sodium-ion batteries.

An embodiment describing a method for producing carbon-coated particles, comprising: positioning nano-ordered carbon particles within a processing region of a processing chamber; purging the processing region containing the nano-ordered nano-ordered carbon particles with an inert gas; heating the nano-ordered carbon particles processing region to a temperature of about 700° C. or greater and wherein the nano-ordered carbon particles are also heated to a temperature of about 700° C.; and depositing a carbon film on the nano-ordered carbon particles to produce carbon-coated particles during a vapor deposition process.

In one embodiment, the inert gas comprises nitrogen (N₂), argon, helium, or any combination thereof. In another embodiment, the nano-ordered carbon particles are heated to a temperature of about 700° C. to about 2,000° C. for about 0.5 minutes to about 20 minutes. In yet another embodiment, the processing region is heated to a temperature of about 700° C. to about 2,000° C. for about 0.5 minutes to about 20 minutes.

In one embodiment, the processing region contains the inert gas when the processing region is heated. In yet another embodiment, the vapor deposition process further comprises: introducing a carbon-containing precursor into the processing region; and heating the processing region to a temperature of about 700° C. to about 2,200° C. for about 1 minute to about 20 minutes, wherein the nano-ordered carbon particles are also heated region to a temperature of about 700° C. to about 2,200° C.

In yet another embodiment, the carbon-containing precursor comprises an alkane, an alkene, an alkyne, an aromatic compound, or any combination thereof. In yet another alternate embodiment, the carbon-containing precursor comprises methane, ethane, propane, butane, pentane, ethylene, propylene, butylene, acetylene, propyne, butyne, benzene, toluene, or any combination thereof. In an alternate embodiment, the carbon-containing precursor comprises a carrier gas selected from nitrogen (N₂), argon, helium, or any combination thereof.

In one embodiment, the vapor deposition process is a thermal decomposition process, a chemical vapor deposition (CVD) process, or a pulsed-CVD process. In yet another embodiment, the carbon film has a thickness of about 1 nm to about 5 µm. In some embodiments, the nano-ordered carbon particles have an average particle size of about 1 µm to about 50 µm. In yet some further embodiments, the carbon-coated particles exhibit an irreversible capacity of less than 55 mAh/g in a battery voltage of about 0 V to about 3 V. In alternate embodiments, the carbon-coated particles have a first cycle efficiency (FCE) of greater than 84%.

In one embodiment, a method is taught for producing carbon-coated particles, comprising: positioning nano-ordered carbon particles within a processing region of a processing chamber, wherein the nano-ordered carbon particles have an average particle size of about 1 µm to about 50 µm; purging the processing region containing the nano-ordered carbon particles with an inert gas; heating the processing region to a temperature of about 700° C. or greater; heating the nano-ordered carbon particles to a temperature of about 700° C. or greater; and introducing a carbon-containing precursor comprising acetylene or toluene into the processing region and exposing the nano-ordered carbon particles to the carbon-containing precursor while depositing a carbon film on the nano-ordered carbon particles and producing carbon-coated particles during a vapor deposition process, wherein the carbon film has a thickness of about 1 nm to about 5 µm.

In another embodiment, the inert gas comprises nitrogen (N₂), argon, helium, or any combination thereof. In one embodiment, the method further comprises heating the nano-ordered carbon particles to a process temperature of about 700° C. to about 2,200° C. for about 1 minute to about 200 minutes during wherein vapor deposition process.

In yet another embodiment, the carbon-containing precursor further comprises a carrier gas selected from nitrogen (N₂), argon, helium, or any combination thereof. In one embodiment, the vapor deposition process is a thermal decomposition process, a chemical vapor deposition (CVD) process, or a pulsed-CVD process. In another embodiment, the carbon-coated particles exhibit an irreversible capacity of less than 55 mAh/g in a battery voltage of about 0 V to about 3 V. In yet another embodiment, the carbon-coated particles have a first cycle efficiency (FCE) of greater than 84%.

In one embodiment, a composition of carbon-coated particles, comprises: an irreversible capacity of less than 55 mAh/g in a battery voltage of about 0 V to about 3 V; and a first cycle efficiency of greater than 84%. In this composition, each carbon-coated particle comprises a carbon film disposed over a nano-ordered carbon particle, wherein: the nano-ordered carbon particles have an average particle size of about 1 µm to about 50 µm; the carbon film has a thickness of about 1 nm to about 5 µm; and the carbon-coated particles have a pore size of about 1 nm to about 3 nm.

In one embodiment of the composition, the irreversible capacity is about 20 mAh/g to about 55 mAh/g and the first cycle efficiency is about 84% to about 95%. In yet another embodiment, the carbon-coated particles is an anode.

In one or more embodiments, nano-ordered carbon (NOCs), such as nano-ordered carbon particles, or other particulates of carbon-containing materials can be used to produce the carbon-coated particles. Exemplary NOCs can be or include hard carbon, char, charcoal, non-graphitizing carbon, or any combination thereof. The nano-ordered carbon particles or other carbon-containing materials can be derived or otherwise produced from one or more carbon sources. In some embodiments, the nano-ordered carbon particles or other carbon-containing materials can be derived or otherwise produced from the carbon-containing components that are produced from a coking reactor, an ethylene cracking reactor, a coal coking unit, a fluid catalytic cracking (FCC) unit, a distillation tower, or other hydrocarbon process system. In one or more examples, nano-ordered carbon particles are produced or otherwise formed from one or more carbonaceous precursors during a carbonization process. Exemplary sources or carbonaceous precursors for the nano-ordered carbon particles or other carbon-containing materials can be or include lignin, one or more sugars, such as sucrose, cellulosic or ligno-cellulosic materials, one or more phenolic resins, one or more polymers, such as polyvinylidene chloride (PVDC), other carbon-based materials and/or hydrocarbon-based materials, or any combination thereof.

In one or more embodiments, the coated hard carbon (e.g., carbon-coated particles) can be prepared, formed, or otherwise produced by positioning nano-ordered carbon particles within or passing the carbon particles through a processing region of a processing chamber, purging the processing region containing the nano-ordered carbon particles with an inert gas, heating the nano-ordered carbon particles during an annealing process, and depositing or forming a carbon film on the nano-ordered carbon particles to produce carbon-coated particles during thermal decomposition and/or a vapor deposition process. Each of the carbon-coated particles has a core-shell structure such that the core contains one or more nano-ordered carbon particles, and the shell contains one or more carbon films at least partially or completely around the core.

The nano-ordered carbon particles can be introduced, positioned, or otherwise placed within the processing region of a processing chamber. The processing chamber can be any type of chamber or reactor for conducting a thermal decomposition and/or a vapor deposition process. Exemplary processing chambers can be or include a furnace, a tube furnace, a reactor, a vessel, an annealing chamber, a vapor deposition chamber (e.g., chemical vapor deposition (CVD) chamber or atomic layer deposition (ALD) chamber), a rotary kiln reactor, a fluidized bed reactor, or other types of chambers. In one or more examples, a processing chamber for conducting a vapor deposition process can be a rotary tube reactor manufactured by Sentro or Harper.

The processing region containing the nano-ordered carbon particles can be purged with one or more inert or purge gases and/or evacuated to remove ambient air. The processing region can be purged and/or evacuated for about 10 seconds, about 30 seconds, or about 45 seconds to about 10 minutes, about 30 minutes, about 60 minutes, or about several hours. The inert gas or purge gas can be or contain nitrogen (N₂), argon, helium, or any combination thereof.

Thereafter, the nano-ordered carbon particles are heated within the processing region to a desired temperature. The nano-ordered carbon particles are heated to a temperature of about 700° C. or greater while the processing region contains the inert gas. The nano-ordered carbon particles are heated to a temperature from a minimum value of about 720° C., about 750° C., about 780° C., about 800° C., about 850° C., or about 900° C. to a maximum value of about 920° C., about 950° C., about 980° C., about 1,000° C., about 1,100° C., about 1,200° C., about 1,500° C., about 1,800° C., about 2,000° C., or greater during the annealing process. For example, the nano-ordered carbon particles are heated to a temperature of about 700° C. to about 2,000° C., about 800° C. to about 2,000° C., about 900° C. to about 2,000° C., about 950° C. to about 2,000° C., about 1,000° C. to about 2,000° C., about 1,200° C. to about 2,000° C., about 1,500° C. to about 2,000° C., about 1,800° C. to about 2,000° C., about 700° C. to about 1,800° C., about 800° C. to about 1,800° C., about 900° C. to about 1,800° C., about 950° C. to about 1,800° C., about 1,000° C. to about 1,800° C., about 1,200° C. to about 1,800° C., about 1,500° C. to about 1,800° C., about 700° C. to about 1,500° C., about 800° C. to about 1,500° C., about 900° C. to about 1,500° C., about 950° C. to about 1,500° C., about 1,000° C. to about 1,500° C., or about 1,200° C. to about 1,500° C.

The nano-ordered carbon particles are heated to the desired temperature for a time period from a minimum value of about 0.5 minutes, about 1 minute, about 2 minutes, about 3 minutes, or about 5 minutes to a maximum value of about 6 minutes, about 8 minutes, about 10 minutes, about 12 minutes, about 15 minutes, about 20 minutes, about 25 minutes, about 30 minutes, or longer during the thermal decomposition and vapor deposition process. For example, the nano-ordered carbon particles are heated to the desired temperature for about 0.5 minutes to about 30 minutes or even several hours, about 0.5 minutes to about 60 minutes, about 0.5 minutes to about 30 minutes, about 0.5 minutes to about 10 minutes, about 0.5 minutes to about 8 minutes, about 0.5 minutes to about 5 minutes, about 0.5 minutes to about 3 minutes, about 0.5 minutes to about 1 minute, about 5 minutes to about 30 minutes, about 5 minutes to about 20 minutes, about 5 minutes to about 15 minutes, about 5 minutes to about 10 minutes, about 5 minutes to about 8 minutes, about 10 minutes to about 30 minutes, about 10 minutes to about 20 minutes, about 10 minutes to about 15 minutes, or about 10 minutes to about 12 minutes during the thermal decomposition and/or vapor deposition process.

In one or more examples, the nano-ordered carbon particles are heated to a temperature of about 800° C. to about 2,000° C. for about 0.5 minutes to about 20 minutes during the annealing process. In other examples, the nano-ordered carbon particles are heated to a temperature of about 900° C. to about 1,800° C. for about 1 minute to about 15 minutes during the annealing process. In some examples, the nano-ordered carbon particles are heated to a temperature of about 1,000° C. to about 1,600° C. for about 5 minutes to about 12 minutes during the annealing process.

The carbon film can be deposited, formed, or otherwise produced on or over the nano-ordered carbon particles by one or more vapor deposition processes. Exemplary vapor deposition processes can be or include a thermal decomposition and deposition processes, chemical vapor deposition (CVD) process, a plasma-enhanced CVD (PECVD), a pulsed-CVD process, a thermal atomic layer deposition (ALD) process, a plasma-enhanced-ALD process, or any combination thereof.

In one or more embodiments, the introduction of the inert or purge gas into the processing region is ceased and a flow of carbon-containing precursor is introduced into the processing region and exposed to the nano-ordered carbon particles during the vapor deposition process. The flow rate is adjusted based on many variables, such as the volume size of the process region, the types of precursors, the reaction temperature, the desired film thickness, and the desired deposition rate, among other conditions. In one or more examples, the carbon-containing precursor can have a flow rate from a minimum value of about 100 mL/min, about 150 mL/min, about 200 mL/min, about 300 mL/min, about 400 mL/min, or about 500 mL/min to a maximum value of about 600 mL/min, about 800 mL/min, about 1,000 mL/min, about 1,500 mL/min, about 2,000 mL/min, about 3,000 mL/min, about 4,000 mL/min, about 5,000 mL/min, or greater during the vapor deposition process. For examples, the carbon-containing precursor can have a flow rate of about 100 mL/min to about 5,000 mL/min, about 100 mL/min to about 4,000 mL/min, about 100 mL/min to about 3,000 mL/min, about 100 mL/min to about 2,000 mL/min, about 100 mL/min to about 1,000 mL/min, about 100 mL/min to about 500 mL/min, about 100 mL/min to about 350 mL/min, about 100 mL/min to about 200 mL/min, about 500 mL/min to about 5,000 mL/min, about 500 mL/min to about 4,000 mL/min, about 500 mL/min to about 3,000 mL/min, about 500 mL/min to about 2,000 mL/min, about 500 mL/min to about 1,000 mL/min, about 500 mL/min to about 800 mL/min, about 1,000 mL/min to about 5,000 mL/min, about 1,000 mL/min to about 4,000 mL/min, about 1,000 mL/min to about 3,000 mL/min, about 1,000 mL/min to about 2,000 mL/min, about 1,000 mL/min to about 1,500 mL/min during the vapor deposition process.

The carbon-containing precursor can include one or more organic compounds and optionally include one or more carrier gases or one or more dilution gases. The carbon-containing precursor can be or contain one or more alkanes, one or more alkenes, one or more alkynes, one or more aromatic compounds, one or more cyclic compounds, other organic compounds, or any combination thereof. Exemplary carbon-containing precursor can be or include methane, ethane, propane, butane, pentane, ethylene, propylene, butylene, acetylene (ethyne), propyne, butyne, benzene, toluene, or any combination thereof. The carrier gas or dilution gas can be or include nitrogen (N₂), argon, helium, neon, or any combination thereof.

The carbon-containing precursor can include the one or more organic compounds at a concentration from a minimum value of about 1 vol% (volume percent), about 2 vol%, about 5 vol%, about 10 vol%, or about 15 vol% to a maximum value of about 20 vol%, about 30 vol%, about 50 vol%, about 80 vol%, about 95 vol%, about 99 vol%, or about 100 vol%, and the remainder of carbon-containing precursor can be the carrier gas and/or the dilution gas. For example, the carbon-containing precursor can include about 1 vol% to about 100 vol%, about 1 vol% to about 99 vol%, about 1 vol% to about 95 vol%, about 1 vol% to about 90 vol%, about 1 vol% to about 75 vol%, about 1 vol% to about 50 vol%, about 1 vol% to about 40 vol%, about 1 vol% to about 20 vol%, about 1 vol% to about 10 vol% of the one or more organic compounds.

In one or more examples, the carbon-containing precursor contains about 1 vol% to about 100 vol% of acetylene, toluene, or another organic compound and from none to about 99 vol% of the carrier gas and/or the dilution gas (e.g., N₂). In other examples, the carbon-containing precursor contains about 1 vol% to about 50 vol% of acetylene, or toluene, or another organic compound and about 50 vol% to about 99 vol% of the carrier gas and/or the dilution gas. In one or more examples, the carbon-containing precursor contains about 1 vol% to about 20 vol% of acetylene, or toluene, or another organic compound and about 80 vol% to about 99 vol% of the carrier gas and/or the dilution gas. In other examples, the carbon-containing precursor contains about 2 vol% to about 10 vol% of acetylene, or toluene, or another organic compound and about 90 vol% to about 98 vol% of the carrier gas and/or the dilution gas. In other examples, the carbon-containing precursor contains about 4 vol% to about 6 vol% of acetylene or another organic compound and about 94 vol% to about 96 vol% of the carrier gas and/or the dilution gas.

The nano-ordered carbon particles are heated to and/or maintained at a process temperature during the vapor deposition process. The nano-ordered carbon particles are heated to a process temperature from a minimum value of about 600° C., about 650° C., about 700° C., about 720° C., about 750° C., about 780° C., about 800° C., about 850° C., or about 900° C. to a maximum value of about 920° C., about 950° C., about 980° C., about 1,000° C., about 1,100° C., about 1,200° C., about 1,500° C., about 1,800° C., about 2,000° C., about 2,200° C., or greater during the vapor deposition process. For example, the nano-ordered carbon particles are heated to a process temperature of about 600° C. to about 2,200° C., about 700° C. to about 2,200° C., about 700° C. to about 2,000° C., about 800° C. to about 2,000° C., about 900° C. to about 2,000° C., about 950° C. to about 2,000° C., about 1,000° C. to about 2,000° C., about 1,200° C. to about 2,000° C., about 1,500° C. to about 2,000° C., about 1,800° C. to about 2,000° C., about 700° C. to about 1,800° C., about 800° C. to about 1,800° C., about 900° C. to about 1,800° C., about 950° C. to about 1,800° C., about 1,000° C. to about 1,800° C., about 1,200° C. to about 1,800° C., about 1,500° C. to about 1,800° C., about 700° C. to about 1,500° C., about 800° C. to about 1,500° C., about 900° C. to about 1,500° C., about 950° C. to about 1,500° C., about 1,000° C. to about 1,500° C., or about 1,200° C. to about 1,500° C. during the vapor deposition process.

The nano-ordered carbon particles are heated to the desired temperature for a time period from a minimum value of about 0.5 minutes, about 1 minute, about 2 minutes, about 3 minutes, or about 5 minutes to a maximum value of about 6 minutes, about 8 minutes, about 10 minutes, about 12 minutes, about 15 minutes, about 20 minutes, about 25 minutes, about 30 minutes, or longer during the vapor deposition process. For example, the nano-ordered carbon particles are heated to the desired temperature for about 0.5 minutes to about 30 minutes or several hours, about 0.5 minutes to about 60 minutes, about 0.5 minutes to about 30 minutes, about 0.5 minutes to about 10 minutes, about 0.5 minutes to about 8 minutes, about 0.5 minutes to about 5 minutes, about 0.5 minutes to about 3 minutes, about 0.5 minutes to about 1 minute, about 5 minutes to about 30 minutes, about 5 minutes to about 20 minutes, about 5 minutes to about 15 minutes, about 5 minutes to about 10 minutes, about 5 minutes to about 8 minutes, about 10 minutes to about 30 minutes, about 10 minutes to about 20 minutes, about 10 minutes to about 15 minutes, or about 10 minutes to about 12 minutes during the vapor deposition process.

In one or more examples, the nano-ordered carbon particles are heated to a process temperature of about 700° C. to about 2,200° C. for about 0.5 minutes to about 120 minutes during the thermal decomposition and/or vapor deposition process. In some examples, the nano-ordered carbon particles are heated to a process temperature of about 800° C. to about 2,000° C. for about 1 minute to about 120 minutes during the thermal decomposition and/or the vapor deposition process. In other examples, the nano-ordered carbon particles are heated to a process temperature of about 900° C. to about 1,800° C. for about 3 minutes to about 15 minutes during the vapor deposition process. In some examples, the nano-ordered carbon particles are heated to a process temperature of about 1,000° C. to about 1,600° C. for about 5 minutes to about 12 minutes during the thermal decomposition and/or the vapor deposition process.

The nano-ordered carbon particles have an average particle size from a minimum value of about 1 µm, about 3 µm, about 5 µm about 8 µm, or about 10 µm to a maximum value of about 12 µm, about 15 µm, about 20 µm, about 25 µm, about 30 µm, about 40 µm, about 50 µm, about 80 µm, or about 100 µm. For example, the nano-ordered carbon particles have an average particle size of about 1 µm to about 100 µm, about 1 µm to about 80 µm, about 1 µm to about 50 µm, about 1 µm to about 40 µm, about 1 µm to about 30 µm, about 1 µm to about 25 µm, about 1 µm to about 20 µm, about 1 µm to about 10 µm, about 1 µm to about 5 µm, about 5 µm to about 100 µm, about 5 µm to about 80 µm, about 5 µm to about 50 µm, about 5 µm to about 40 µm, about 5 µm to about 30 µm, about 5 µm to about 25 µm, about 5 µm to about 20 µm, about 5 µm to about 10 µm, about 10 µm to about 100 µm, about 10 µm to about 80 µm, about 10 µm to about 50 µm, about 10 µm to about 40 µm, about 10 µm to about 30 µm, about 10 µm to about 25 µm, about 10 µm to about 20 µm, or about 10 µm to about 15 µm.

In one or more embodiments, the nano-ordered carbon particles contain greater than 95 wt% (weight percent) of hard carbon. The nano-ordered carbon particles contain a concentration of hard carbon from a minimum value of about 95.5 wt%, about 96 wt%, or about 97 wt% to a maximum value of about 98 wt%, about 98.5 wt%, about 99 wt%, about 99.5 wt%, about 99.9 wt%, or 100 wt% of hard carbon. For example, the nano-ordered carbon particles contain about 95.5 wt% to about 100 wt%, about 95.5 wt% to about 99.9 wt%, about 96 wt% to about 99.9 wt%, about 97 wt% to about 99.9 wt%, about 98 wt% to about 99.9 wt%, about 99 wt% to about 99.9 wt%, about 99.5 wt% to about 99.9 wt%, about 95.5 wt% to about 99 wt%, about 96 wt% to about 99 wt%, about 97 wt% to about 99 wt%, or about 98 wt% to about 99 wt% of hard carbon.

The carbon film on or over the nano-ordered carbon particles has a thickness from a minimum value of about 1 nm, about 2 nm, about 3 nm, about 5 nm, about 8 nm, about 10 nm, about 12 nm, or about 15 nm to a maximum value of about 18 nm, about 20 nm, about 25 nm, about 30 nm, about 50 nm, about 80 nm, about 100 nm, about 150 nm, about 200 nm, about 300 nm, about 500 nm, about 800 nm, about 1 µm, about 2 µm, about 3 µm, or about 5 µm. For example, the carbon film on or over the nano-ordered carbon particles has a thickness of about 1 nm to about 5 µm, about 1 nm to about 3 µm, about 1 nm to about 2 µm, about 1 nm to about 1 µm, about 1 nm to about 500 nm, about 1 nm to about 300 nm, about 1 nm to about 200 nm, about 1 nm to about 100 nm, about 1 nm to about 50 nm, about 1 nm to about 20 nm, about 1 nm to about 10 nm, about 1 nm to about 5 nm, about 5 nm to about 5 µm, about 5 nm to about 3 µm, about 5 nm to about 2 µm, about 5 nm to about 1 µm, about 5 nm to about 500 nm, about 5 nm to about 300 nm, about 5 nm to about 200 nm, about 5 nm to about 100 nm, about 5 nm to about 50 nm, about 5 nm to about 20 nm, about 5 nm to about 10 nm, about 50 nm to about 5 µm, about 50 nm to about 3 µm, about 50 nm to about 2 µm, about 50 nm to about 1 µm, about 50 nm to about 500 nm, about 50 nm to about 300 nm, about 50 nm to about 200 nm, about 50 nm to about 100 nm, or about 50 nm to about 80 nm.

The carbon film contains greater than 95 wt% of carbon. The carbon film contains carbon at a concentration of a minimum value from about 95.5 wt%, about 96 wt%, or about 97 wt% to a maximum value of about 98 wt%, about 98.5 wt%, about 99 wt%, about 99.5 wt%, about 99.9 wt%, or 100 wt% of carbon. For example, the carbon film contains about 95.5 wt% to about 100 wt%, about 95.5 wt% to about 99.9 wt%, about 96 wt% to about 99.9 wt%, about 97 wt% to about 99.9 wt%, about 98 wt% to about 99.9 wt%, about 99 wt% to about 99.9 wt%, about 99.5 wt% to about 99.9 wt%, about 95.5 wt% to about 99 wt%, about 96 wt% to about 99 wt%, about 97 wt% to about 99 wt%, or about 98 wt% to about 99 wt% of carbon.

The carbon-coated particles have an average particle size slightly larger than the average particle size of the underlying nano-ordered carbon particles before being coated. The average particle size carbon-coated particles is about two times the thickness of the film coating the underlying nano-ordered carbon particles. The carbon-coated particles have an average particle size of a minimum value from about 1 µm, about 3 µm, about 5 µm about 8 µm, or about 10 µm to a maximum value of about 12 µm, about 15 µm, about 20 µm, about 25 µm, about 30 µm, about 40 µm, about 50 µm, about 80 µm, or about 100 µm. For example, the carbon-coated particles have an average particle size of about 1 µm to about 100 µm, about 1 µm to about 80 µm, about 1 µm to about 50 µm, about 1 µm to about 40 µm, about 1 µm to about 30 µm, about 1 µm to about 25 µm, about 1 µm to about 20 µm, about 1 µm to about 10 µm, about 1 µm to about 5 µm, about 5 µm to about 100 µm, about 5 µm to about 80 µm, about 5 µm to about 50 µm, about 5 µm to about 40 µm, about 5 µm to about 30 µm, about 5 µm to about 25 µm, about 5 µm to about 20 µm, about 5 µm to about 10 µm, about 10 µm to about 100 µm, about 10 µm to about 80 µm, about 10 µm to about 50 µm, about 10 µm to about 40 µm, about 10 µm to about 30 µm, about 10 µm to about 25 µm, about 10 µm to about 20 µm, or about 10 µm to about 15 µm.

The carbon-coated particles exhibit an irreversible capacity of less than 55 mAh/g in a battery voltage of about 0 V to about 3 V. The carbon-coated particles exhibit an irreversible capacity from a minimum value of about 20 mAh/g, about 30 mAh/g, about 35 mAh/g, about 38 mAh/g, or about 40 mAh/g to a maximum value of about 42 mAh/g, about 44 mAh/g, about 45 mAh/g, about 46 mAh/g, about 48 mAh/g, about 50 mAh/g, about 52 mAh/g, about 53 mAh/g, about 54 mAh/g, or less than 55 mAh/g. For example, the carbon-coated particles exhibit an irreversible capacity of about 20 mAh/g to less than 55 mAh/g, about 30 mAh/g to less than 55 mAh/g, about 35 mAh/g to less than 55 mAh/g, about 40 mAh/g to less than 42 mAh/g, about 45 mAh/g to less than 55 mAh/g, about 48 mAh/g to less than 55 mAh/g, about 50 mAh/g to less than 55 mAh/g, about 20 mAh/g to about 54 mAh/g, about 30 mAh/g to about 54 mAh/g, about 35 mAh/g to about 54 mAh/g, about 40 mAh/g to about 54 mAh/g, about 45 mAh/g to about 54 mAh/g, about 48 mAh/g to about 54 mAh/g, about 50 mAh/g to about 54 mAh/g, about 25 mAh/g to about 52 mAh/g, about 30 mAh/g to about 52 mAh/g, about 35 mAh/g to about 52 mAh/g, about 40 mAh/g to about 52 mAh/g, about 20 mAh/g to about 50 mAh/g, about 30 mAh/g to about 50 mAh/g, about 35 mAh/g to about 50 mAh/g, about 40 mAh/g to about 50 mAh/g, about 45 mAh/g to about 50 mAh/g, or about 48 mAh/g to about 50 mAh/g.

### Examples

In order to provide a better understanding of the foregoing discussion, the following non-limiting examples are offered. Although the examples can be directed to specific embodiments, they are not to be viewed as limiting the invention in any specific respect.

The positive results due to the carbon film on the nano-ordered carbon particles are highlighted in the below Examples. The carbon film is deposited on the nano-ordered carbon particles and provides improved properties over the nano-ordered carbon particles without a coating of the carbon film.

Comparative Example 1 (CEx1) - A comparative sample (about 1 g) of non-coated nano-ordered carbon particles with a particle size of about 10 µm was used to make Battery 1, as further discussed below. The comparative sample is the same type of nano-ordered carbon particles as used as a starting material in Example 1.

Example 1 (Ex 1) - A sample (about 1 g) of nano-ordered carbon particles with a particle size of about 10 µm was placed into the center of a tube furnace and maintained at ambient temperature (about 23° C.). A stream of inert gas containing nitrogen (N₂) was flowed into the tube furnace at a rate of about 300 sccm, across the sample and out the exhaust of the tube furnace. After about 60 mins to about 120 mins of being exposed to the inert gas at ambient temperature, the tube furnace has activated to heat the sample while the sample was exposed with the inert gas. Once the sample reached a temperature of about 800° C., the inert gas was stopped and a precursor gas containing about 5 vol% of acetylene and about 95 vol% of N₂ was exposed to the sample during a thermal decomposition and/or vapor deposition process. The sample was maintained at a temperature of about 800° C. while being exposed to the precursor gas for about 10 mins at a rate of about 300 sccm to produce a coating of carbon film on the nano-ordered carbon particles. Thereafter, the precursor gas was stopped and the inert gas was exposed to the sample for about 10 mins.

Battery 1 - An anode was made from the non-coated nano-ordered carbon particles (CEX1), a cathode, and electrolyte. The electrode slurry contains about 90 wt% of hard carbon, 5 wt% of carbon black, and 5 wt% of PVDF binder. The slurry was fully mixed and coated on aluminum foil. The prepared electrode was vacuum dried and punched into disks (1.76 cm²) with hard carbon loading of 5-6 mg/disk. The hard carbon working electrode and sodium foil counter/reference electrode were separated by a piece of glass fiber (Whatman® FG/B), filled with electrolyte. The base electrolyte contains 1 M NaPF₆ in ethylene carbonate (EC) and dimethyl carbonate (DMC) (1:1 in volume). The cell was initially charged at a constant current of 0.10 mA until the cell voltage reached 0.0 V then held at 0.0 V until the current was less than 0.0010 mA. On discharging, the cell was discharged at 0.10 mA until the cut-off voltage (2.0 V) was reached. A total of 5 cycles were conducted.

Battery 2 - An anode was made from the carbon film coated nano-ordered carbon particles (EX1), a cathode, and electrolyte. The electrode slurry contains about 90 wt% of carbon film coated hard carbon, about 5 wt% of carbon black, and about 5 wt% of PVDF binder. The slurry was fully mixed and coated on aluminum foil. The prepared electrode was vacuum dried and punched into disks (1.76 cm²) with hard carbon loading of 5-6 mg/disk. The hard carbon working electrode and sodium foil counter/reference electrode were separated by a piece of glass fiber (Whatman® FG/B), filled with electrolyte. The base electrolyte consisted of 1 M NaPF₆ in ethylene carbonate (EC) and dimethyl carbonate (DMC) (1:1 in volume). The cell was initially charged at a constant current of 0.10 mA until the cell voltage reached 0.0 V then held at 0.0 V until the current was less than 0.0010 mA. On discharging, the cell was discharged at 0.10 mA until the cut-off voltage (2.0 V) was reached. A total of 5 cycles were conducted.

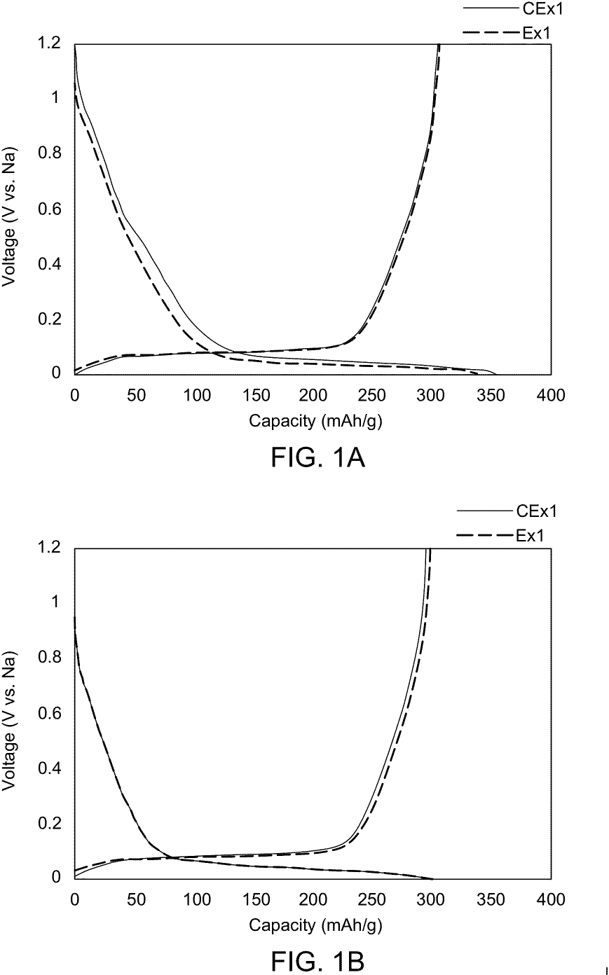

FIGS. 1A and 1B are graphs illustrating voltage versus capacity after a first cycle (FIG. 1A) and a second cycle (FIG. 1B) for a battery containing coated hard carbon of Ex1 compared to a control battery containing non-coated hard carbon of CEx1. The charge potential of the battery containing coated hard carbon of Ex1 quickly drops to lower potentials relative to the control battery containing non-coated hard carbon of CEx1. This lower charge potential indicated that the coated hard carbon of Ex1 substantially reduced the capacity loss during the first cycle. For example, the irreversible capacity for the non-coated hard carbon of CEx1 was about -60 mAh/g, while the irreversible capacity for the coated hard carbon of Ex1 was about -50 mAh/g. Also, the first cycle efficiency for the non-coated hard carbon of CEx1 was about -84%, while the first cycle efficiency for the coated hard carbon of Ex1 was about -86%. Therefore, the carbon film coated nano-ordered carbon particles have a reduced irreversible capacity and an increased first cycle efficiency over the non-coated nano-ordered carbon particles.

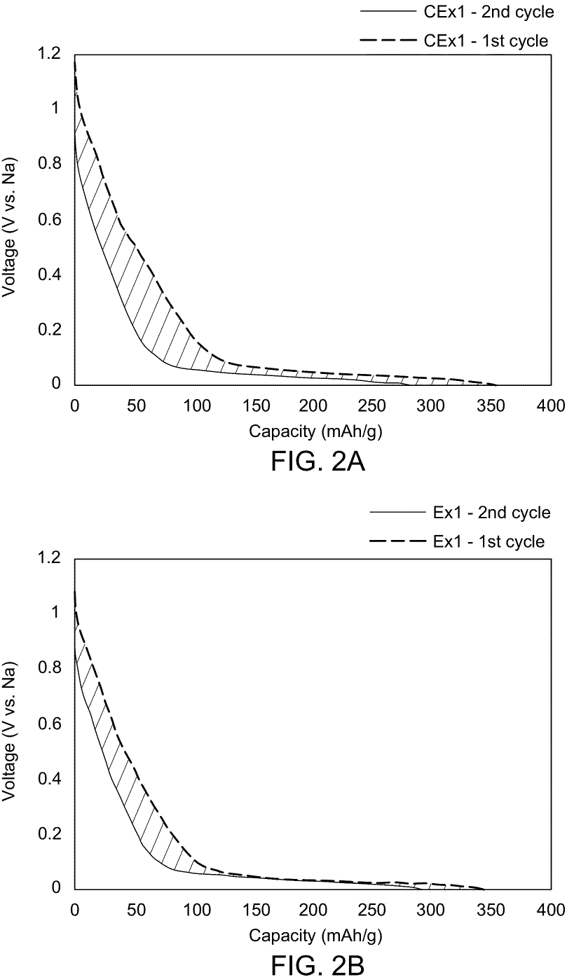

FIG. 2A is a graph illustrating a comparison of the first and second charge profiles of a control battery containing the non-coated hard carbon of CEx1 and FIG. 2B is a graph illustrating a comparison of the first and second charge profiles of a battery containing the coated hard carbon of Ex1. The control battery containing the non-coated hard carbon of CEx1 produced the graph in FIG. 2A which illustrates the shaded areas representing the difference between the first and second cycles and correspond to the charge energy loss about 20% to about 40%. The non-coated hard carbon of CEx1 showed energy loss in the slopping area of the graph as well as substantial energy loss of about 10% to about 20% in the plateau region of the graph.

The battery containing the coated hard carbon of Ex1 produced the graph in FIG. 2A which illustrates the shaded areas representing the difference between the first and second cycles and correspond to the charge energy loss. The shaded area represents the charge energy loss (sodiation) during the formation cycle. In contrast to the control battery, the battery containing the coated hard carbon of Ex1 had a greater reduced energy loss of about 10% to about 30% in the slopping region of the graph and even a greater reduction of energy loss of about 0% to about 10%in the plateau region of the graph.

Example 2 - hard carbon materials were prepared from the heavy fraction (>830° F.) of a refinery slurry oil. In a typical experiment, 5 g heavy cut was functionalized through a multi-step air oxidation process. The feedstock was first placed in a large rectangle crucible and oxidized in a muffle furnace with a programmed temperature profile (ramping to 250-320° C. at 3° C./min and hold for 12 h). After the mild oxidation, the intermediate was ground into powder and set in the muffle furnace again for oxidation at 250-320° C. for 12 h. The highly oxidized pitch was carbonized in a laboratory tube furnace under nitrogen atmosphere at 1100° C. for 2 h. The produced hard carbon was labeled as C1100.

Example 3 - The hard carbon material (C1100) produced from example 2 was uniformly spread on a flat substrate with <1 mm thickness and then set in the middle of a tube reactor. The system temperature was raised to 800° C. at a ramp rate of 5° C./min with 300 sccm N2 flow. Upon reaching 800° C., the N2 flow was switched to flow through a bubbler containing toluene. After exposing the sample to toluene-containing gas for 2 h, the gas flow was switched back to pure N2 line.

Example 4 - hard carbon materials were prepared from the heavy fraction (>830° F.) of a refinery slurry oil. In a typical experiment, 5 g heavy cut was functionalized through a multi-step air oxidation process. The feedstock was first placed in a large rectangle crucible and oxidized in a muffle furnace with a programmed temperature profile (ramping to 250-320° C. at 3° C./min and hold for 12 h). After the mild oxidation, the intermediate was ground into powder and set in the muffle furnace again for oxidation at 250-320° C. for 12 h. The highly oxidized pitch was carbonized in a laboratory tube furnace under nitrogen atmosphere at 1200° C. for 2 h. The produced hard carbon was labeled as C1200.

Example 5 - The hard carbon material (C1200) produced from example 2 was uniformly spread on a flat substrate with <1 mm thickness and then set in the middle of a tube reactor. The system temperature was raised to 800° C. at a ramp rate of 5° C./min with 300 sccm N2 flow. Upon reaching 800° C., the N2 flow was switched to flow through a bubbler containing toluene. After exposing the sample to toluene-containing gas for 2 h, the gas flow was switched back to pure N2 line.

Example 6 - hard carbon materials were prepared from the heavy fraction (>830° F.) of a refinery slurry oil. In a typical experiment, 5 g heavy cut was functionalized through a multi-step air oxidation process. The feedstock was first placed in a large rectangle crucible and oxidized in a muffle furnace with a programmed temperature profile (ramping to 250-320° C. at 3° C./min and hold for 12 h). After the mild oxidation, the intermediate was ground into powder and set in the muffle furnace again for oxidation at 250-320° C. for 12 h. The highly oxidized pitch was carbonized in a laboratory tube furnace under nitrogen atmosphere at 1300° C. for 2 h. The produced hard carbon was labeled as C1300.

Example 7 - The hard carbon material (C1300) produced from example 2 was uniformly spread on a flat substrate with <1 mm thickness and then set in the middle of a tube reactor. The system temperature was raised to 800° C. at a ramp rate of 5° C./min with 300 sccm N2 flow. Upon reaching 800° C., the N2 flow was switched to flow through a bubbler containing toluene. After exposing the sample to toluene-containing gas for 2 h, the gas flow was switched back to pure N2 line.

Example 8 - hard carbon materials were prepared from the heavy fraction (>830° F.) of a refinery slurry oil. In a typical experiment, 5 g heavy cut was functionalized through a multi-step air oxidation process. The feedstock was first placed in a large rectangle crucible and oxidized in a muffle furnace with a programmed temperature profile (ramping to 250-320° C. at 3° C./min and hold for 12 h). After the mild oxidation, the intermediate was ground into powder and set in the muffle furnace again for oxidation at 250-320° C. for 12 h. The highly oxidized pitch was carbonized in a laboratory tube furnace under nitrogen atmosphere at 1400° C. for 2 h. The produced hard carbon was labeled as C1400.

Example 9 - The hard carbon material (C1400) produced from example 2 was uniformly spread on a flat substrate with <1 mm thickness and then set in the middle of a tube reactor. The system temperature was raised to 800° C. at a ramp rate of 5° C./min with 300 sccm N2 flow. Upon reaching 800° C., the N2 flow was switched to flow through a bubbler containing toluene. After exposing the sample to toluene-containing gas for 2 h, the gas flow was switched back to pure N2 line.

Preparation of Electrode - The nano-ordered carbon products prepared from example 2-9 were made into electrode for electrochemical evaluation. The electrodes were prepared by casting a well-mixed dispersion of hard carbon: alginate binder: carbon black (90:5:5 in weight) in water onto a carbon-coated copper substrate with a doctor blade to form a thin film. The electrode film was then dried in a vacuum oven at 80° C. for 1 h.

Preparation of Coin Cells for Sodium and Lithium-ion half-cell tests -- Disks with 1.5 cm diameter were punched out from the electrode films using a die cutter (MTI™ MSK-T-07). The mass loading of active materials on these disks varied from 5 to 6 mg/disc. Each sodium ion coin cell was prepared in an argon-filled glovebox by sequentially stacking a Na metal as anode, a separator (a layer of Whatman® glass fiber filter), an electrode disk as cathode, a stainless steel disk spacer, and a wave spring in a bottom can. An electrolyte of 1 M NaPF6 in 50 vol % ethylene carbonate and 50 vol % dimethyl carbonate (purchased from Sigma-AldrichⓇ was added to the separator before the electrode disk was stacked. After the top can was placed over the bottom can, the assembly was crimped and sealed by a coin cell crimper (MTI™ MSK-110). In the case of preparing lithium-ion coin cells, a Li metal disc was used as anode and a solution of 1 M LiPF6 in 40 vol % ethylene carbonate, 30 vol % dimethyl carbonate, and 30 vol % diethyl carbonate (purchased from Sigma-AldrichⓇ) was injected as electrolyte. The electrochemical tests were performed on a battery tester (Neware® BTS4000 for sodium ion cells and Arbin® potentiostat/galvanostat for lithium-ion cells). The electrical charge passed during each charge/discharge cycle was recorded and used to calculate the specific capacity and coulombic efficiency. All the tests were conducted at ambient temperature.

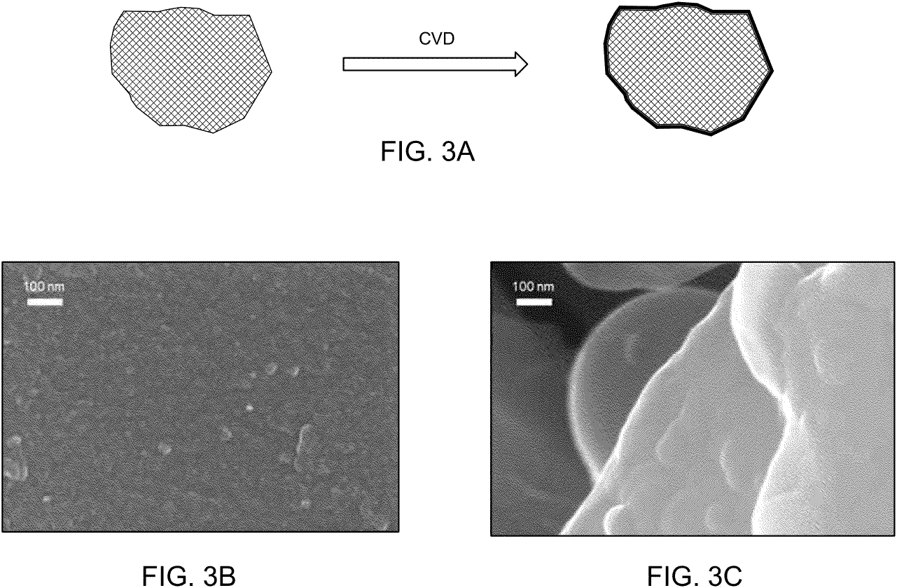

Example 2, 4, 6, and 8 produced a series of hard carbon samples that were carbonized at different temperatures (1100-1400° C.): these samples were denoted as C1100, C1200, C1300, and C1400 respectively. These samples were further coated by thermal decomposition of toluene in Example 3, 5, 7, and 9. The surface morphologies of these samples were observed with scanning electron microscopy. As shown in FIG. 3, a typical hard carbon surface without coating exhibits rough texture at nano scale. After coating via thermal decomposition of toluene, the surface appears relatively smoother, indicating change in surface morphology by carbon coating. Hypothetically, the new surface would reduce the overall surface area and hence the number of active sites for parasitic side reactions, resulting in improved FCE.

FIG. 3A depicts a schematic coating on a hard carbon particle.

FIG. 3B depicts high resolution SEM images before coating.

FIG. 3C depicts high resolution SEM images after coating.

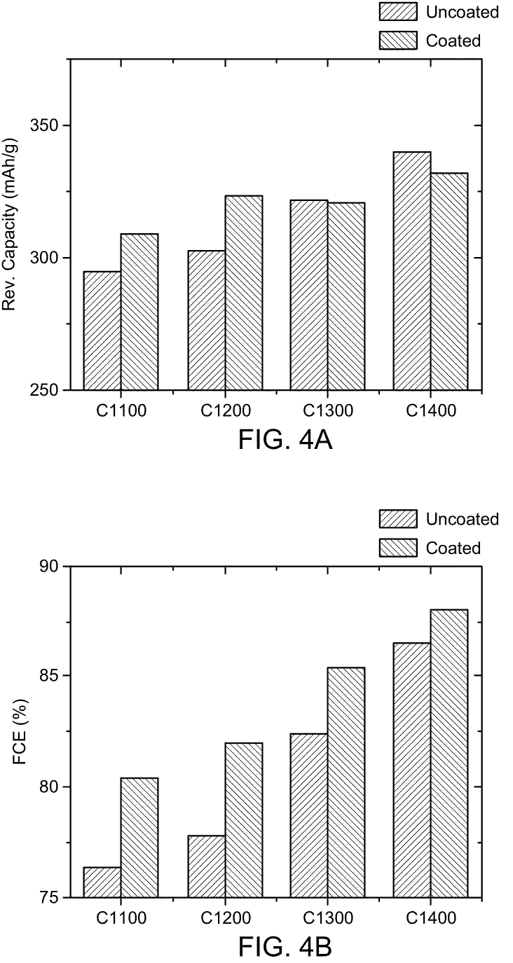

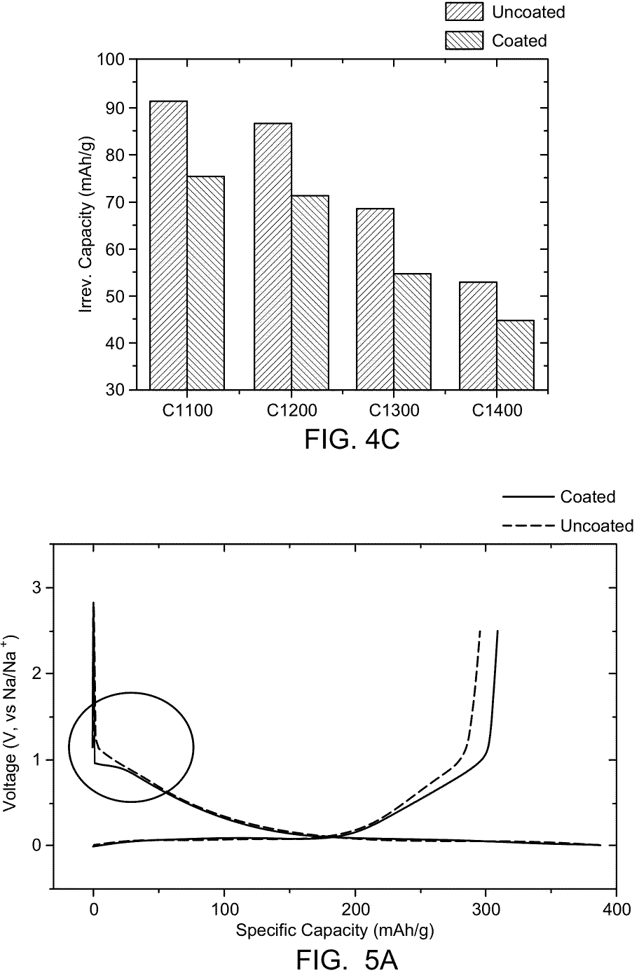

The series of hard carbon samples were fabricated into electrodes, which were tested in sodium ion hall cells. Improvement of FCEs have been found on all the tested samples (FIG. 4), agreeing with the hypothesis. The FCE of original C1400, the highest (86.5%) among other uncoated hard carbon samples, was increased to 88%. The enhancement is even greater for samples carbonized at lower temperatures, which have lower FCEs in the original form. For instance, C1100 saw a boost in FCE from 76.4% to 80.4%. This resulted in an increase in reversible capacity from 295 mAh/g to 309 mAh/g, for coated sample C1200, the reversible capacity was further boosted to 324 mAh/g, which was only able to be achieved at higher carbonization temperature without coating.

FIG. 4A depicts a graph of reversible capacities in sodium ion half cells for hard carbon samples before and after coating.

FIG. 4B depicts a graph of FCEs in sodium ion half cells for hard carbon samples before and after coating.

FIG. 4C depicts a graph of irreversible capacities in sodium ion half cells for hard carbon samples before and after coating.

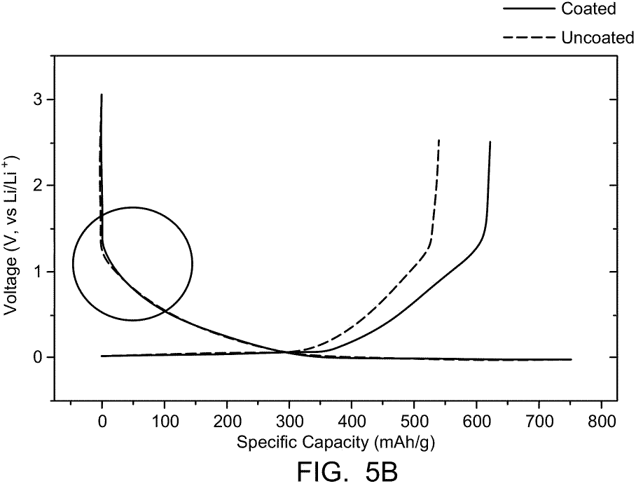

The discharge/charge profiles during the first cycle were examined to investigate the effect of carbon coating on the interaction of electrolyte/solvent and carbon surface. The red circle in FIG. 5 highlights the change of initial sodiation profile after the coating was applied. The onset potential of initial sodiation was push down to ~1 V from ~1.2 V, followed by a small plateau area (around 20 mAh/g), indicating new interfacial interaction on the modified carbon surface. This phenomenon was observed from voltage profiles for all the samples. It could be formation of different type of solid electrolyte interface (SEI) layer, or conversion of active sites that catalyze irreversible side reactions into sites that can reversibly bond Na ions or inert sites. As a result, the portion of desodiation capacity in the sloping section (>0.15 V) increased by ~14 mAh/g while the plateau region capacity (<0.15 V) remained almost the same, which confirms a hypothesis that is shared by most of debating theories about Na ion storage mechanism in hard carbon: a large fraction of sloping region capacity is contributed from adsorption of Na ions on defective and/or edge sites.

FIG. 5A depicts the reversible capacity and FCE in sodium ion half cells for nano-ordered carbon C1100 before and after coating.

FIG. 5B depicts the FCE in lithium-ion half cells for hard carbon C1100 before and after coating.

The impact of coating on the Li ion storage in hard carbon was also evaluated. C1100 sample was selected for LIB half-cell test. A significant boost in performance was observed: FCE was increased from 77% to 83%; reversible capacity was raised from 541 mAh/g to 623 mAh/g, 67% higher than theoretical capacity (372 mAh/g) of Li ions in graphite. The super high capacity of hard carbon for Li ion storage could be assigned to the available types of storage sites. The possible sites for Li+ storage hypothetically include defective sites on the plain or edge of graphene sheets, interspace between flexible graphene sheets, and nano-pores encased by curved or entangled graphene stacks/sheets. In contrast, the majority of sites in graphite materials is solely the interspace between orderly stacked graphene sheets. When the carbon coating was applied on C1100 surface, the interaction of the modified surface with solvated Li salt seems different from solvated Na salt, which is evidenced by the almost indistinguishable initial lithiation profiles (red circle area in FIGS. 5A and B). It seems the interfacial interaction is likely conversion of active sites that catalyze irreversible side reactions into sites that can reversibly bond Li ions. As a result, the majority of capacity gain came from the increase in the sloping region capacity.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term "comprising" is considered synonymous with the term "including" for purposes of United States law. Likewise, whenever a composition, an element, or a group of elements is preceded with the transitional phrase "comprising", it is understood that the same composition or group of elements with transitional phrases "consisting essentially of", "consisting of", "selected from the group of consisting of", or "is" preceding the recitation of the composition, element, or elements and vice versa, are contemplated. As used herein, the term "about" refers to a +/-10% variation from the nominal value. It is to be understood that such a variation can be included in any value provided herein.

Certain embodiments and features have been described using a set of numerical minimum values and a set of numerical maximum values. It should be appreciated that ranges including the combination of any two values, e.g., the combination of any minimum value with any maximum value, the combination of any two minimum values, and/or the combination of any two maximum values are contemplated unless otherwise indicated. Certain minimum values, maximum values, and ranges appear in one or more claims below.

What is claimed is:

1. A method for producing carbon-coated particles, comprising:
positioning nano-ordered carbon particles within a processing region of a processing chamber;
purging the processing region containing the nano-ordered nano-ordered carbon particles with an inert gas;
heating the processing region to a temperature of about 700° C. or greater and wherein the nano-ordered carbon particles are also heated to a temperature of about 700° C.; and
depositing a carbon film on the nano-ordered carbon particles to produce carbon-coated particles during a vapor deposition process.

2. The method of claim 1, wherein the inert gas comprises nitrogen (N₂), argon, helium, or any combination thereof.

3. The method of claim 1, wherein the nano-ordered carbon particles are heated to a temperature of about 700° C. to about 2,000° C. for about 0.5 minutes to about 20 minutes.

4. The method of claim 1, wherein the processing region is heated to a temperature of about 700° C. to about 2,000° C. for about 0.5 minutes to about 20 minutes.

5. The method of claim 1, wherein the processing region contains the inert gas when the processing region is heated.

6. The method of claim 1, wherein the vapor deposition process further comprises:
introducing a carbon-containing precursor into the processing region; and
heating the processing region to a temperature of about 700° C. to about 2,200° C. for about 1 minute to about 20 minutes, wherein the nano-ordered carbon particles are also heated region to a temperature of about 700° C. to about 2,200° C.

7. The method of claim 6, wherein the carbon-containing precursor comprises an alkane, an alkene, an alkyne, an aromatic compound, or any combination thereof.

8. The method of claim 6, wherein the carbon-containing precursor comprises methane, ethane, propane, butane, pentane, ethylene, propylene, butylene, acetylene, propyne, butyne, benzene, toluene, or any combination thereof.

9. The method of claim 6, wherein the carbon-containing precursor comprises a carrier gas selected from nitrogen (N₂), argon, helium, or any combination thereof.

10. The method of claim 1, wherein the vapor deposition process is a thermal decomposition process, a chemical vapor deposition (CVD) process, or a pulsed-CVD process.

11. The method of claim 1, wherein the carbon film has a thickness of about 1 nm to about 5 µm.

12. The method of claim 1, wherein the nano-ordered carbon particles have an average particle size of about 1 µm to about 50 µm.

13. The method of claim 1, wherein the carbon-coated particles exhibit an irreversible capacity of less than 55 mAh/g in a battery voltage of about 0 V to about 3 V.

14. The method of claim 1, wherein the carbon-coated particles have a first cycle efficiency (FCE) of greater than 84%.

15. A method for producing carbon-coated particles, comprising:
positioning nano-ordered carbon particles within a processing region of a processing chamber, wherein the nano-ordered carbon particles have an average particle size of about 1 µm to about 50 µm ;
purging the processing region containing the nano-ordered carbon particles with an inert gas;
heating the processing region to a temperature of about 700° C. or greater;
heating the nano-ordered carbon particles to a temperature of about 700° C. or greater; and
introducing a carbon-containing precursor comprising acetylene or toluene into the processing region and exposing the nano-ordered carbon particles to the carbon-containing precursor while depositing a carbon film on the nano-ordered carbon particles and producing carbon-coated particles during a vapor deposition process, wherein the carbon film has a thickness of about 1 nm to about 5 µm.

16. The method of claim 15, wherein the inert gas comprises nitrogen (N₂), argon, helium, or any combination thereof.

17. The method of claim 15, further comprising heating the nano-ordered carbon particles to a process temperature of about 700° C. to about 2,200° C. for about 1 minute to about 200 minutes during wherein vapor deposition process.

18. The method of claim 15, wherein the carbon-containing precursor further comprises a carrier gas selected from nitrogen (N₂), argon, helium, or any combination thereof.

19. The method of claim 15, wherein the vapor deposition process is a thermal decomposition process, a chemical vapor deposition (CVD) process, or a pulsed-CVD process.

20. The method of claim 15, wherein the carbon-coated particles exhibit an irreversible capacity of less than 55 mAh/g in a battery voltage of about 0 V to about 3 V.

21. The method of claim 15, wherein the carbon-coated particles have a first cycle efficiency (FCE) of greater than 84%.

22. A composition of carbon-coated particles, comprising:
an irreversible capacity of less than 55 mAh/g in a battery voltage of about 0 V to about 3 V; and
a first cycle efficiency of greater than 84%;
each carbon-coated particle comprises a carbon film disposed over a nano-ordered carbon particle, wherein:
the nano-ordered carbon particles have an average particle size of about 1 µm to about 50 µm;
the carbon film has a thickness of about 1 nm to about 5 µm; and
the carbon-coated particles have a pore size of about 1 nm to about 3 nm.

23. The composition of claim 22, wherein the irreversible capacity is about 20 mAh/g to about 55 mAh/g and the first cycle efficiency is about 84% to about 95%.

24. An anode comprising the carbon-coated particles of claim 22.
